(19) United States
(12) Patent Application Publication
(10) Pub. No.: US 2009/0015239 A1
(43) Pub. Date: Jan. 15, 2009

(54) Transmission Line Sensor

(76) Inventors: George E. Georgiou, Gillette, NJ (US); Ken K. Chin, Pine Brook, NJ (US); Raymond Ferraro, Howell, NJ (US); Guanhua Feng, Dover, NJ (US); Karen Gail Noe, Wall Township, NJ (US)

Correspondence Address: GIBSON & DERNIER L.L.P., 900 ROUTE 9 NORTH, SUITE 504, WOODBRIDGE, NJ, 07095, US

(21) Appl. No.: 12/041,228

(22) Filed: Mar. 3, 2008

Related U.S. Application Data
(60) Provisional application No. 60/892,353, filed on Mar. 1, 2007.

(51) Int. Cl. G01R 19/32

(52) U.S. Cl. 324/105

(57) ABSTRACT

A system and method in which an overhead high voltage transmission line sensor system is able to measure one or more of temperature, current, and line sag for a conductor within a high voltage transmission line system. The sensor system may be able to clamp to a transmission conductor or splice, harvest power from the transmission line, and/or transmit data corresponding to measurements of current, temperature, and line sag.

### CROSS-REFERENCE TO RELATED APPLICATIONS

This application claims the benefit of U.S. Provisional Patent Application Ser. No. 60/892,353, filed Mar. 1, 2007, entitled “Overhead High Voltage Transmission Line Remote Sensor”, the entire disclosure of which is hereby incorporated by reference herein.

### BACKGROUND OF THE INVENTION

The present invention relates in general to transmission line monitoring and in particular to systems and methods for conducting such monitoring in a more efficient and reliable manner than do existing approaches.

The electric power supply system is potentially a target for terrorist sabotage because a major disruption of services would virtually paralyze the area affected, leading to panic and chaos. Natural disasters, such as hurricanes and major thunderstorms, as well as overloading of the power grid, can also inflict severe human suffering and economic losses.

Most system and/or component failures, either man-made or natural, however, develop gradually. For example, the large scale US northeast blackout of August 2004 was due to a high voltage transmission conductor overheating, which caused a transmission line to sag, and touch a tree. In addition, several PSE&G (Public Service Electric & Gas Company of Newark, N.J.) high voltage transmission line ruptures were due to defects in splicing connectors of the transmission line conductors.

One existing monitoring device is manufactured by USI. It is a donut shaped device, which has a diameter of 32 cm (centimeters) diameter, is 14 cm wide, and weights 10 kg. Due to its large size, large weight and high cost, the USI device can only practically be installed as a rating device, and not as a monitoring device installed in thousands of sections of the power grid.

### SUMMARY OF THE INVENTION

An overhead high voltage transmission line remote sensor is provided. The remote sensor preferably includes an electronics chamber that transmits overhead high voltage line data to a base station. The remote sensor also preferably includes a clamping mechanism. The clamping mechanism may be adapted to clamp the remote sensor to an overhead high voltage transmission line. The remote sensor may also include a coupling device that couples the electronics chamber to the clamping mechanism. Preferably, the coupling device obtains reduced thermal contact between the clamping mechanism and the electronics chamber.

One or more embodiments of the present invention relate to the configuration and design of an overhead high voltage transmission line real time remote sensor and data acquisition system, which is low cost in manufacturing and installation. More specifically, an embodiment of the present invention is directed to an overhead high voltage transmission line sensor that can also be used as a rating device. An embodiment of the present invention relates to providing certain functionality that can be found with existing commercial rating devices at less than half of the size and weight of the existing commercial rating devices.

Other aspects, features, advantages, etc. will become apparent to one skilled in the art when the description of the preferred embodiments of the invention herein is taken in conjunction with the accompanying drawings.

### BRIEF DESCRIPTION OF THE DRAWINGS

For the purposes of illustrating the various aspects of the invention, there are shown in the drawings forms that are presently preferred, it being understood, however, that the invention is not limited to the precise arrangements and instrumentalities shown.

FIG. 1A is a schematic end view of a transmission line remote sensor, according to an embodiment of the invention;

FIG. 1B is a schematic side view of the transmission line remote sensor of FIG. 1A, according to an embodiment of the invention;

FIG. 2A is a perspective view of a transmission line remote sensor according to an embodiment of the invention;

FIG. 2B is a perspective view of a retroactive installation of the device of FIG. 1C on a transmission line according to an embodiment of the invention;

FIG. 3 is a schematic view of a portion of the sensor of FIG. 1 showing an electrical interface that may be operable to harvest power and/or to measure transmission line current flowing in conductor according to an embodiment of the invention;

FIG. 4 is a perspective view of an apparatus for harvesting power and measuring transmission line current according to an embodiment of the invention;

FIG. 5 is a schematic diagram of a system for monitoring a temperature difference between a conductor and a splice according to an embodiment of the invention;

FIG. 6 is a perspective view of a system for monitoring a temperature difference between a conductor and a splice by using infrared detectors according to an embodiment of the invention;

FIG. 7 is a perspective view of a system for monitoring transmission line sag, using a liquid level with a light absorption gradient according to an embodiment of the invention;

FIG. 8 is a block diagram of a transmitter module according to an embodiment of the invention;

FIG. 9 is a block diagram of a data collection architecture that may include a wireless network layer/data communication intermediary and a central master control according to an embodiment of the invention;

FIG. 10 is a perspective view of the remote sensor assembly showing a receiver unit with LCD display according to an embodiment of the invention;

FIG. 11 is a block diagram of a transmitter module having multiple data inputs according to an embodiment of the invention;

FIG. 12 is a schematic diagram of a sensor module enclosure including a single remote unit straddling a conductor/splice and collecting data from both the conductor and splice, according to an embodiment of the invention;

FIG. 13 is a sectional end view of a power line enclosed within a clamped enclosure forming part of a remote unit in which thermal insulator spokes may be used to reduce heat flow to the remote sensor unit electronics; and

FIG. 14 is a schematic view of a power harvesting system according to an embodiment of the invention; and

FIG. 15 is a schematic view of a power harvesting system according to another embodiment of the invention.

### DETAILED DESCRIPTION OF THE PREFERRED EMBODIMENTS

The objects and advantages of the invention will be apparent upon consideration of the following detailed description, taken in conjunction with the accompanying drawings, in which like reference characters refer to like parts throughout.

In the following description, for purposes of explanation, specific numbers, materials and configurations are set forth in order to provide a thorough understanding of the invention. It will be apparent, however, to one having ordinary skill in the art that the invention may be practiced without these specific details. In some instances, well-known features may be omitted or simplified so as not to obscure the present invention. Furthermore, reference in the specification to phrases such as “one embodiment” or “an embodiment” means that a particular feature, structure or characteristic described in connection with the embodiment is included in at least one embodiment of the invention. The appearances of phrases such as “in one embodiment” or “in an embodiment” in various places in the specification do not necessarily all refer to the same embodiment.

Various benefits may be obtained through real-time remote monitoring of various parameters of the power grid overhead transmission line conductors, including but not limited to: a) current, b) temperature, and/or c) sagging of the conductors (conductor line sag). First, early detection of symptoms indicative of future or imminent failure, such as excessive line sagging, or a splice temperature higher than that of a neighboring conductor, can guide power industry crews to locate and fix a problem before it causes catastrophic failure. Second, such monitoring can serve the purpose of rating the power system. Finding of extreme over-redundancy of capacity can help utility companies utilize the system with more efficiency, saving millions of dollars in building new transmission lines. The term rating as used herein is explained as follows. Each power line has a maximum current-carrying capability related to the maximum temperature rating of the materials used in the construction of the power line. Real-time monitoring of the “rating” of a power line indicates how close a currently prevailing transmission line current through the power line is to the maximum current allowed for that power line. A power grid is built with redundancy for the sake of reliability. This may allow the network operator to shift current load from one transmission line connecting points A and B to another redundant transmission line connecting the same points A and B.

A power grid is built with redundancy for reliability. This possibly allows the network operator to shift current load from one transmission line connecting points A and B to another redundant transmission line connecting the same points A and B.

For existing power lines, remote monitoring devices may be retrofitted into the existing power grid. For power lines not yet in existence, remote monitoring devices may be integrated into new overhead transmission lines as the new lines are constructed. Herein, remote monitoring devices are also referred to as “remote sensors” or simply as “sensor systems.”

### I. Configuration of the Overhead High Voltage Transmission Line Remote Sensor

Herein, high voltage transmission lines may refer to transmission lines having voltages such as, but not limited to 230 KV (Kilo-Volts), 500 KV, or 750 KV. However, the invention is not limited to the use of the listed voltages. High voltage transmission lines, as discussed herein, may be located either overhead or underground. The invention is not limited to either of the foregoing transmission line locations.

A high voltage transmission line remote sensor according to the invention preferably may perform the following functions: a) clamping a sensor system to a conductor or splice; b) harvesting power from the transmission line to provide DC (direct current) operating power to the sensor system, c) measuring desired parameters (such as line current, temperature and line sag) of the transmission line; and/or d) transmitting the measured data to a central communications hub, such as a utility control center, of a power-grid data communication network.

Preferably, the power harvesting operates over a wide range of currents (between several hundred amps (amperes) to several thousand amps) possible in the various parts of the power grid.

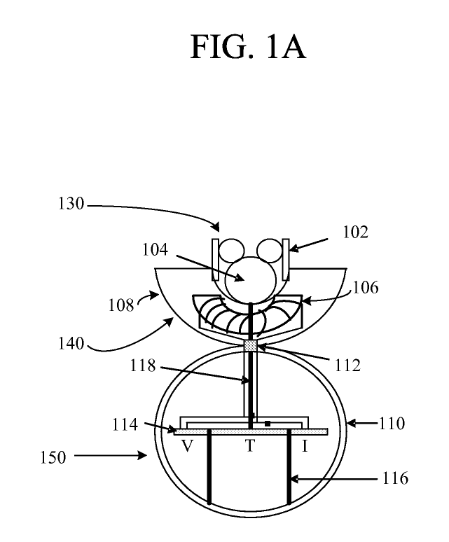

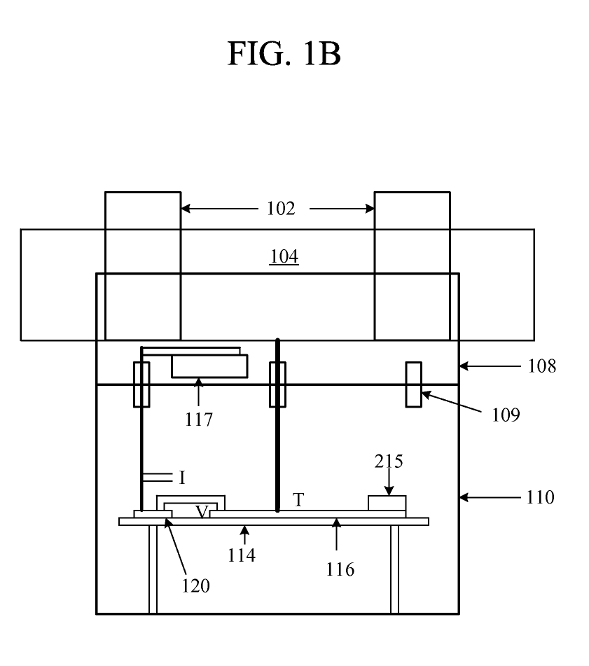

FIG. 1A shows sensor system 100 in accordance with one embodiment of the invention. Sensor system 100 may include main portions that include clamping mechanism 130, power system 140, and/or electronics chamber 150. Clamping mechanism 130 is the upper portion of sensor system 100 of FIG. 1A, and electronics chamber (also referred to herein as “sensor electronics” or “sensor circuit”) 140. A more complete listing of the parts forming one embodiment of sensor system 100 follows.

Sensor system 100 may include spring and roller clamp assembly 102, conductor splice 104, power harvesting coupling coil 106, clamp body 108, electronics housing 110, connecting screw 112, electronics PCB (Printed Circuit Board) 114, insulating standoffs 116, and/or thermocouple 118. In some embodiments of sensor system 100, one or more of the above-listed devices may be omitted. Conversely, sensor system 100 is not limited to including only the parts listed above. Above, conductor splice 104 was recited as forming part of sensor system 100 for the sake of convenience. However, in some embodiments, splice 104 may be a standard part of a power grid and may not be a part of an installed sensor system 100. In other embodiments, splice 104 may customized to accommodate sensor system 100 and/or may form a part thereof.

Referring to FIG. 1A, the upper section is the clamping mechanism 130 (shown for retrofitting onto existing transmission lines), the middle section 140 (power system) has the shape of a half donut with a power harvesting induction coil 106 in it, and the bottom section may include electronics chamber 150, which may be a void circular cylinder with both ends rounded to avoid electrical corona. The power harvesting chamber 140 and the electronics chamber 150 are preferably sealed so as to be substantially weatherproof.

In this embodiment, the three above-described sections may be connected using three pairs of bolts and nuts made of material with low thermal conductivity such as Teflon®. However, other materials may be employed for the nuts and bolts. The middle bolt may have a larger diameter than the other bolts, and may have a hole therein for power harvesting wiring and/or for thermocouple 118. Thermocouple 118 may extend from the power harvesting chamber 140 to the electronics chamber 150. Three washers (not shown) made of thermally insulating material may be placed between the two chambers 140, 150 to improve the aerodynamic quality and tolerance for severe weather of the sensor 100. The power harvesting chamber 140 is preferably at same temperature as the transmission line conductor or splice 104, the design limit for this temperature being about 250° C. The electronics chamber 150 may be close to the environmental temperature, thus well below 150° C., the highest temperature permitted for safe and sound operation of suitable electronic components.

The various components are connected as described in the following. The spring loaded roller clamp 102 may be mounted on the clamp body 102 which securely fits around the conductor or splice 104. The power harvesting coil 106 may be stored within clamp body 108. Coil 106 may inductively couple with the current of conductor 104 to provide an output voltage which is rectified to provide operating power (V) to PCB 114. Calculations may be performed to convert the voltage detected at coil 106 into the conductor current (I) This process thereby enables measuring the current through the high voltage transmission line.

Continuing with the description, the electronics housing 110 may be attached to clamp body 108 using connecting screw 112. Electronics housing 110 of electronics chamber 150 may enclose PCB 114 with the measurement and rectification electronics, insulating standoff 116, and at least a portion of thermocouple 118. Insulating standoff 116 may be used to secure PCB 114 to an interior of electronics housing 110.

In an embodiment, power harvested from coil 106 may be rectified, and provided to PCB 114 to enable processing measurement data for temperature (T), line sag (S), and/or conductor current (I).

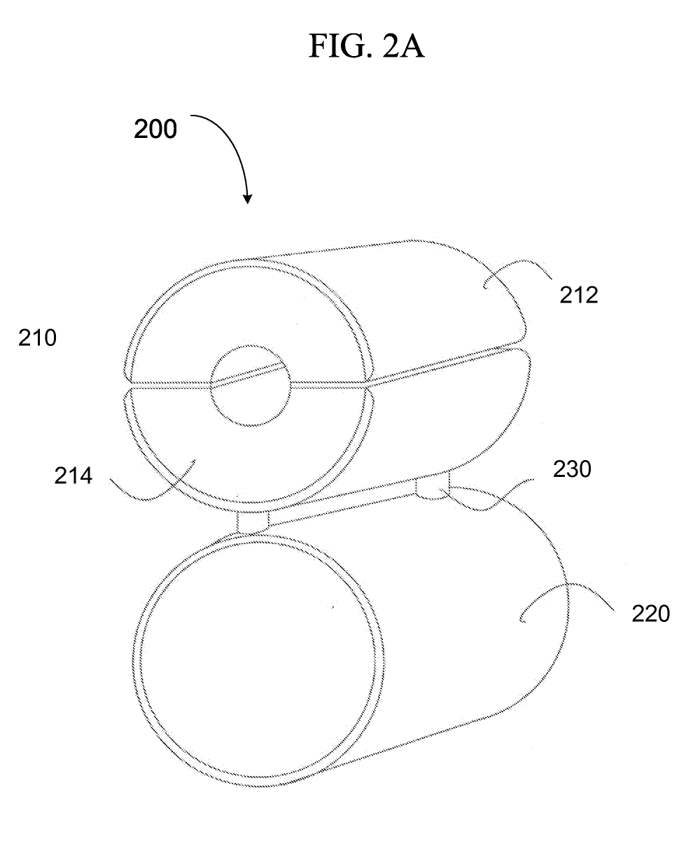

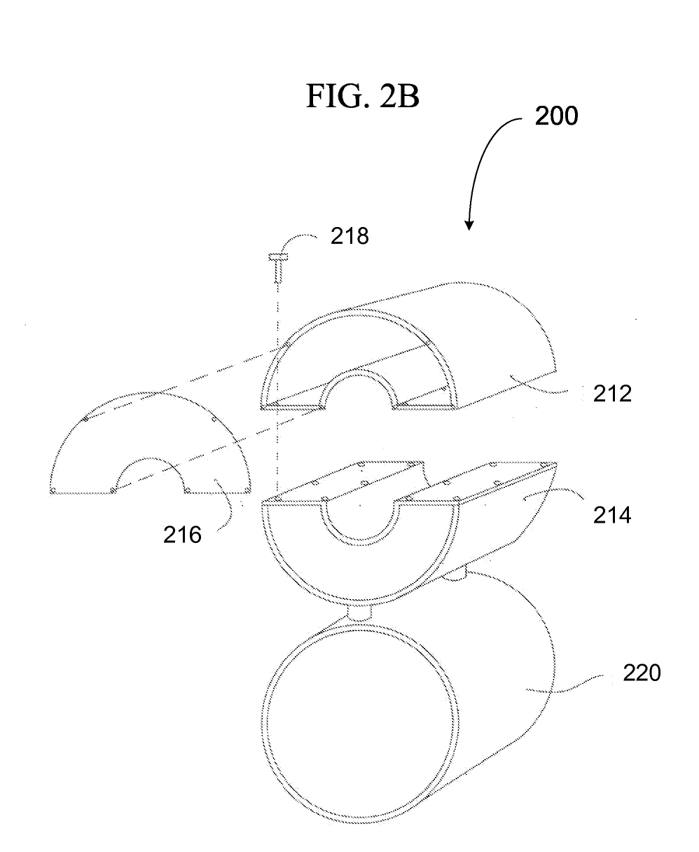

In an embodiment, when sensors 100 are installed in a new transmission line on the ground, the clamping of the sensor 100 to the conductor or splice 104 may be accomplished using four conventional screws as shown in FIG. 2 and described in the portion of the specification corresponding thereto.

FIG. 1B is a schematic side view of sensor system 100 illustrating the mounting of the electronics housing 110 to clamp body 108 with coupling screws 109. The described attachment preferably provides an interface between electronics housing 110 and clamp body 108 which includes a line contact with minimum thermal contact. FIG. 1B also shows spring/roller clamps 102, and splice/conductor 104. FIG. 1B also shows PCB 114 which may include rectifier electronics 120, measurement electronics 116, which may perform analog signal conditioning, and/or transmitter 115 for transmitting the gathered data 215 (such as temperature T, conductor current I and conductor sag). Preferably, the harvested power is rectified using power harvest coil 117.

The development of a prototype housing according to the invention may be simplified by removing the spring/roller clamps 102, and using a split ring to clamp around the splice or conductor 104.

A prototype housing according to the invention is shown in FIG. 2A. It should be noted that since the power grid does not have standard diameter splices and cables, the clamp diameter can be made for the largest size and retrofitted to smaller sizes using appropriate inserts. This practical consideration reduces inventory and installation confusion.

Specifically FIG. 2A shows a configuration of a transmission line remote sensor 200. This embodiment may be implemented with a split hollow ring 210 (also upper chamber 210) that may include upper portion 212 and lower portion 214, that may be clamped around the splice/conductor (not shown). The lower portion 214 preferably contains the power harvesting coil (FIG. 1). Electronics chamber 220 may contain rectification and sensing electronics. Minimal thermal contact between the chambers 210, 220 may be implemented by employing a coupling 230 that is of the smallest size that will still provide sufficient structural strength.

FIG. 2B shows an installation of sensor 200 on a new transmission line (not shown). FIG. 2B shows how clamping cover 216 may be secured to upper portion 212 and lower portion 214 of hollow ring 210 using screw 218.

Alternatively, the sensor 200 may also be retroactively installed on an existing transmission line using either the spring/roller mechanism 102 (FIG. 1) or the clamp/screw mechanism 218 (FIG. 2). For the spring/roller mechanism 102, a specially designed utility truck with hydraulic post having 3-D (Three-Dimensional) maneuvering capability may be used to push the sensor up while the transmission conductor is being held down. In this case, performing a retroactive installation in this manner, without a technician using a “hot stick”, as is known in the art, may reduce installation cost by an order of magnitude or more.

Alternatively, where the approach of FIG. 2B using screw 218 is employed, a technician may be required to complete the installation of sensor 200. In this case the cost savings realized with the spring/roller installation will not be experienced.

One preferred method for installation may be to use the remote sensor 100 having spring/roller mechanism 102. Again, a utility truck with a hydraulic post having 3-D maneuvering capability may be helpful for installing the sensor up while the transmission conductor is being held down.

### Harvesting Power and Measuring the Line Current

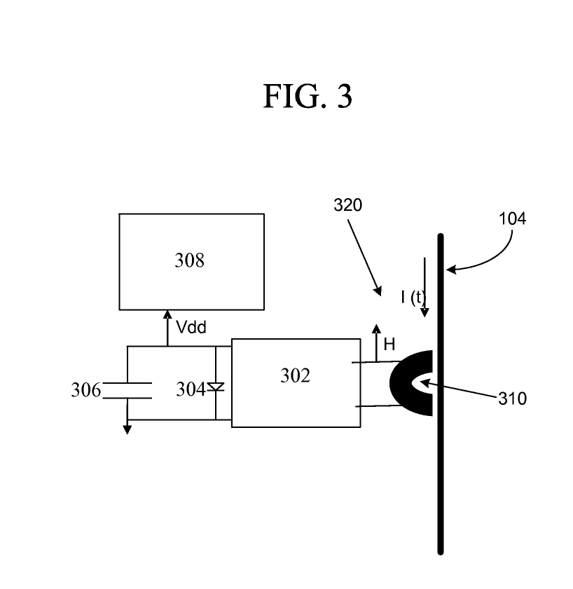

Due to the limited lifetime of most batteries, (about 2 years for lithium batteries) and the high cost of battery replacement, in a preferred embodiment of the invention, a power harvesting system may be implemented to provide power to electronic systems within sensor system 100. FIG. 3 shows the design principle of the power harvesting used in one embodiment of a remote sensor unit 100 according the invention.

FIG. 3 is a schematic view of a portion of the sensor of FIG. 1 showing an electrical interface 300, of sensor 100, that may be operable to harvest power and/or to measure transmission line current flowing in conductor 104 according to an embodiment of the invention.

In an embodiment, electrical interface 300 may include power harvesting circuit 320, and/or measurement electronics 308. More specifically, electrical interface 300 may include a magnetic induction apparatus 310 (such as, but not limited to toroidal winding 310), a rectifier 302, which may be a full-bridge rectifier coupled to the induction apparatus 310. Electrical interface 300 may further include clamping diode 304 in communication with rectifier 302, capacitor 306 coupled to diode 304, and/or measuring electronics and transmitter 308, which may be operable to receive an operating DC voltage Vdd from power harvesting circuit 320.

Magnetic induction apparatus 310 may be a toroidal winding extending over any desired angular range around conductor 104. For instance, toroidal winding 310 may form a complete or half circle around conductor 104, or cover any desired angular range about conductor 104 greater than, or less than, a half circle.

Rectifier 302 may be a full bridge rectifier. The voltage V generated at rectifier 302 is generated in accordance with the formula V=L (dI/dt), where L is inductance of the toroid and I is the current through the conductor 104. The value of L may be established based on the number of wire turns on toroid 310 as is known in the art. The variables of power harvesting system 320 (which may include at least toroid 310 and rectifier 302) may be established so as to generate an output of 5 volts DC even when the AC (Alternating Current) current through the conductor 104 is at a minimum level within a range of seasonal AC current fluctuation.

Diode 304 may provide Vdd of 5 volts for the full range of H generated by toroid 310. Capacitor 306 may be configured to provide sufficient energy storage so as to provide power at the desired voltage even when AC current I through conductor 104 falls below a minimum design value.

In this embodiment, the induced 60 Hz AC voltage output in the toroid 310 is rectified by rectifier 302 to produce a DC voltage, the magnitude of which is proportional to the transmission line 104 current, and therefore may be used as a signal indicative of the transmission line current. Clamping diode 304 may provide a voltage output Vdd=5V for a full range of H. Capacitor 306, which preferably continuously stores energy received from rectifier 302 may provide power to measuring electronics 308 even when I(t) is below the minimum design value.

It should be noted that the value of I(t) may be derived from the value of H. The DC power output from rectifier 302 charges capacitor 306, which may be kept at a constant level of 5 VDC to supply power to measuring electronics 308. The power harvesting and current measurement circuit 300 may be operable at any level of the VA (power) of the transmission line 104.

Even though power harvesting may provide a potentially infinite source of power, the power available from capacitor 306 is finite. Long periods of sensor operation may be required when I(t) of conductor 104 is below the minimum value needed for power harvesting. For example, it may be desired to prove that the sensor 100 functions on a transmission conductor 104 which is out of service. Thus, power consumption of the electronics 308 still should be minimized to allow for long periods of operation without significantly drawing down the charge of capacitor 306. The life of the electronics power supply can be extended at least by (1) using the sleep mode feature of ICs; (2) transmitting data only when the data change is significant; and/or (3) programming long intervals between data transmissions, when the data change is not significant.

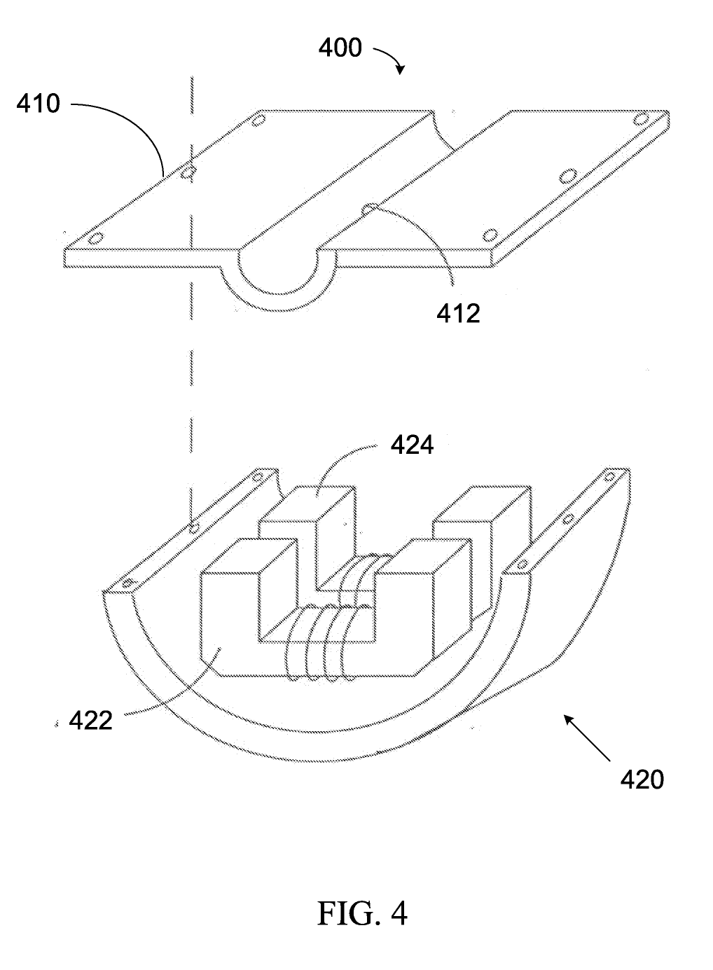

FIG. 4 is a perspective view of an apparatus for harvesting power and measuring transmission line current according to an embodiment of the invention. Thus, power harvesting apparatus 400 may generally correspond to magnetic induction apparatus 310 of FIG. 3.

Apparatus 400 may include upper clamping shell 410 and lower clamping shell 420. Upper clamping shell 410 may include a recess 412, having a circular cross section, to accommodate the placement of a thermocouple (not shown) therein. Lower clamping shell 420 may enclose one or more coils 422, 424. In this embodiment, lower clamping shell 420 may enclose first coil 422 and second coil 424. In this embodiment, coil 422 may be used to generate power for electronic circuits of sensor 100; and coil 424 may be used to measure the current I of conductor 104 (FIG. 3).

### Measurement of the Temperature Difference of Conductor and Splice

In most cases, the breaking of conductors within a power grid occurs at splices. Under normal operation, the electric power transmission line splice is at a lower temperature than the neighboring conductor because the diameter of the splice is greater than that of the conductor, and therefore has better heat dissipation. Infrared photos of transmission line systems have shown that in some cases splices are hotter than nearby portions of the conductor, which situation may be caused by poor quality splice manufacturing, by installation errors, and/or by severe weather conditions that damage the splice or conductor. Thus, in one embodiment of the invention, the monitoring of temperature of the transmission line conductor is directed to measuring of the temperature difference between a splice and portions of a conductor close to the splice.

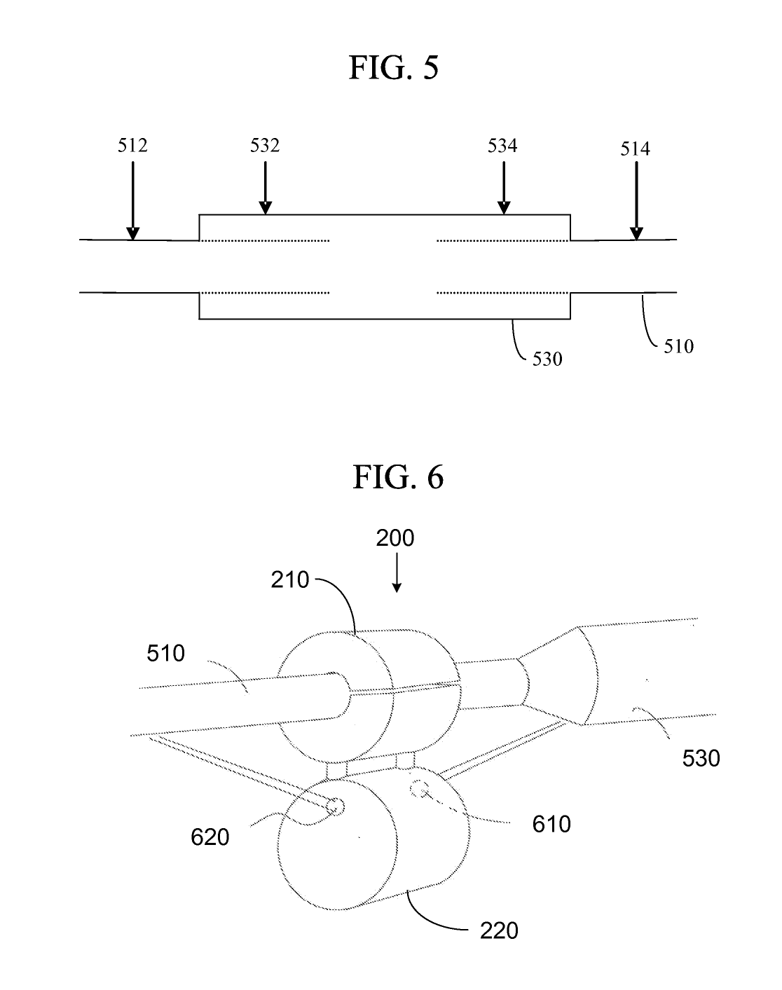

One way to determine this temperature difference is to implement substantially identical sensor units at appropriate locations on the splice, and on the transmission line conductor close to an end of the splice, respectively. The concept is shown in FIG. 5 for a splice using four sensors with four respective thermocouples.

FIG. 5 is a schematic diagram of a system for monitoring a temperature difference between a conductor 510 and a splice 530 according to an embodiment of the invention. Specifically, FIG. 5 shows monitoring of temperature difference between the conductor 510 and the splice 530 by using thermocouples. In one embodiment, conductor 510 is made of steel-reinforced aluminum. However, any suitable material may be used. Splice 530 may also be made of aluminum. However, any suitable material may be used for splice 530.

For a through splice as shown in FIG. 5, two pairs of data are taken. Data may be collected for conductor 510 at locations 512 and 514, and for splice 530 at locations 532 and 534. In this embodiment, the measurement points for both conductor 510 and splice 530 may all be about one foot away from the junction points between the conductor 510 and the splice 530.

The use of two sensors 200 on splice 530 may be redundant. In this embodiment, the splice 530 material is aluminum, and the temperature/current data are not expected to change significantly over the length of splice 530. In the case where conductor 510 terminates at a customer facility or transformer, the terminal splice (not shown) may be only half the length of the length of splice 530 shown in FIG. 5. Thus, for a terminal splice as described above, data from a total of two locations may suffice: that is, one conductor data point and one splice data point.

FIG. 6 is a perspective view of a system for monitoring a temperature difference between a conductor 510 and a splice 530 by using infrared detectors 610, 620 according to an embodiment of the invention.

FIG. 6 shows conductor 510 extending toward splice 530 with sensor 200 coupled to a length of conductor 510. As introduced earlier herein, sensor 200 includes upper chamber 210 and electronics chamber 220. Infrared sensors (detectors) 610 and 620 are shown disposed on outer surfaces of electronics chamber 220 of sensor 200.

In this embodiment, two non-contact infrared detectors 610, 620 may be disposed at respective ends of the electronics chamber 220. Commercial infrared detectors may measure temperature of a surface with an accuracy of about 0.1° C., independent of the emissivity of the surface, the temperature of which is being measured.

The arrangement of FIG. 6 may enable monitoring conditions at a through splice using two sensors 200, instead of using 304 sensors 200. Specifically, the embodiment of FIG. 6 shows a system for monitoring temperature difference between conductor 510 and splice 530 by using infrared detectors 610, 620.

It is noted that the described non-contact approach to measuring temperature uses infrared detectors to detect the infrared radiation emitted from surfaces of the objects having their temperature measured. Such surfaces are typically at higher temperatures than the rest of the objects in question because of the emissivity of the surface being measured by the infrared detectors. However, measuring several wavelengths with the infrared detectors 610, 620 allows sensor system 200 to calculate the emissivity (which changes with time for example from weather related factors) of the object being measured. Thus, the surface temperature can be corrected for any changes in surface emissivity, thereby providing a corrected temperature measurement for the overall object for which a temperature measurement is sought. Employing the above-described approach, the recited 0.1° C. accuracy of the commercial infrared detectors is preferably obtained.

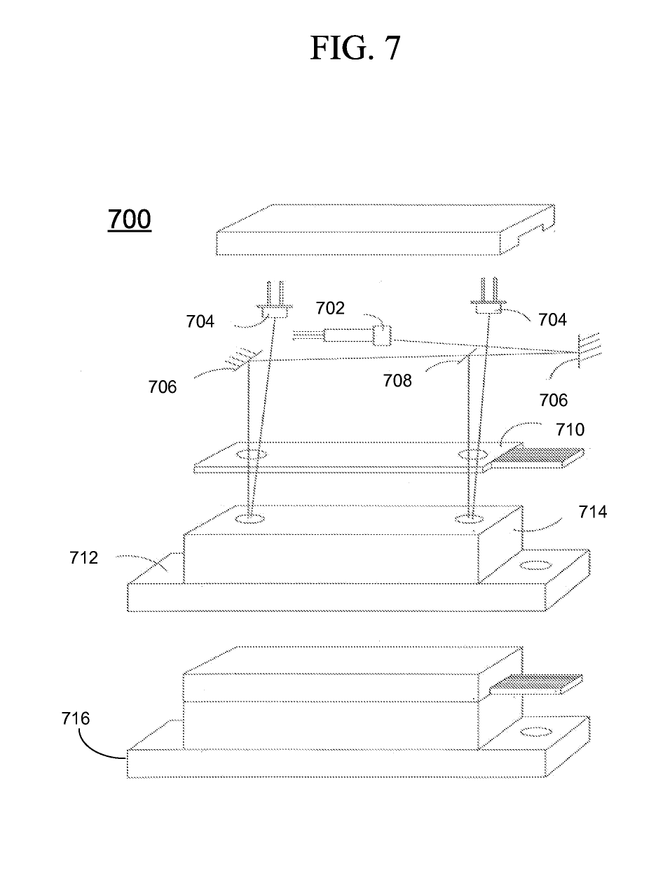

FIG. 7 is a perspective view of a system 700 for monitoring transmission line sag using a liquid level with a light absorption gradient according to an embodiment of the invention.

FIG. 7 shows monitoring of transmission line sag by using a liquid level with a light absorption gradient. Specifically, FIG. 7 shows 650 nm laser module 702, detectors 704, mirror 706, beam splitter 708, electronics and optical assembly board 710, liquid container 714, and level foundation 712. Base 716 and cover 718 may also be included in assembly 700.

### Measurement of Line Sag

In the embodiment of FIG. 7, a level 700 with length equal to the length of the electronics chamber is installed to sense line sag. The liquid of the level 700 is preferably a strong absorbent of the light of the two light emitting devices (LEDs) 704. The sag of a transmission line to which level measuring system 700 is connected causes the level foundation 712 to incline, resulting in the intensity difference of the outputs of the two LEDs 704, which may be linked to the inputs of a differential operational amplifier.

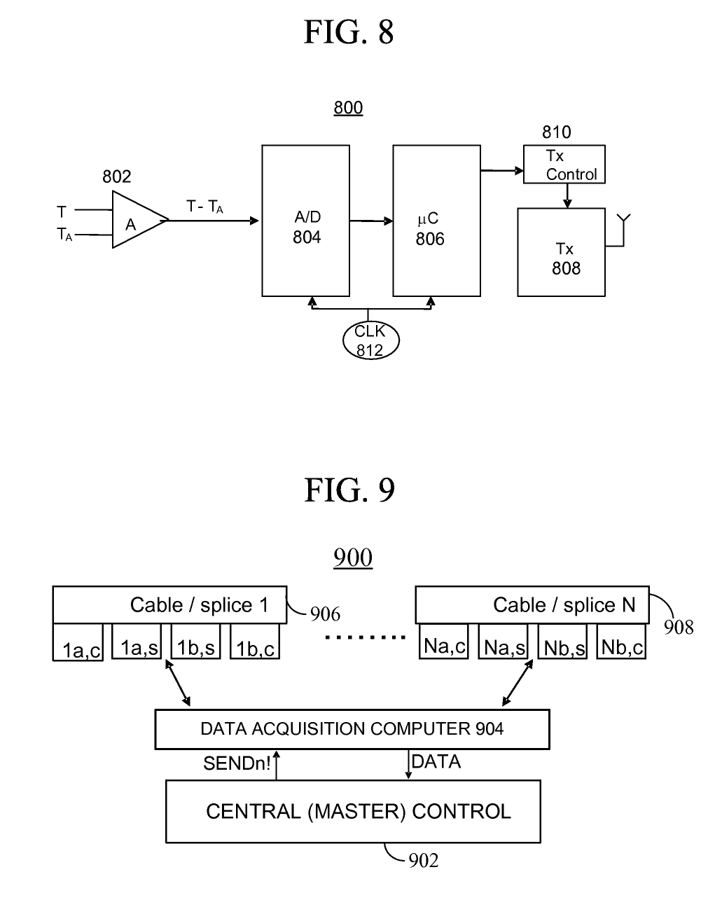

To obtain a maximum signal as a function of line sag, the remote sensor unit 200 may be installed next to a bushing (not shown). In the following, reference is made to electronic components such as those shown in FIG. 8. It will be appreciated that FIG. 8 illustrative of a circuit that may be used with an embodiment of the present invention. The invention is not limited to the precise features of the circuit of FIG. 8.

The analog output of the amplifier 802 may be digitized to render the line inclination angular signal θ, which is related to the line deflection or vertical sagging “d,” as shown in the equations below.

$$d = \frac{l}{2 tan θ} [ cosh ( \frac{L}{l} tan θ ) - 1 ] = \frac{1}{4} \frac{{L}^{2}}{l} tan θ ( 1 + \frac{1}{12} \frac{{L}^{2}}{{l}^{2}} {tan}^{2} θ + … ) \qquad ( 1 )$$

where L is the span of the transmission line between the bushings at the line supporting towers, and l is the length of the conductor after stretching due to stress and heating.

The mid point tension of the line H is horizontal

$$H = \frac{W}{2 tan θ} \qquad ( 2 )$$

Under the condition that θ is small, the tension at the end of the line next to the bushing insulator and tower, is slightly greater than H.

The tension H is related to the length “l”, weight W, cross section area A, Young's modulus E, thermal expansion coefficient α and temperature T of the line with respect to a reference temperature To (for example 0° C.).

$$\begin{matrix}l = L [ 1 + α ( T - {T}_{o} ) + \frac{H}{AE} ] \\ = \frac{2 HL}{W} sinh \frac{W}{2 H} \\ = \frac{2 HL}{W} [ \frac{1}{1 !} \frac{W}{2 H} + \frac{1}{3 !} {( \frac{W}{2 H} )}^{3} + … ]\end{matrix} \qquad ( 3 )$$

Equation (3) can be used to cross check and correct the measured line temperature T and angular sagging signal θ. Preferably, all the necessary parameters of the transmission line, such as sagging d and tension H, can be calculated with software using the measured data at the central ground control station.

Thus, the relationship between line inclination angle θ and the transmission line vertical sag d, line tension H, and line temperature T are shown by foregoing equations (1), (2) and (3).

### Remote Data Transmission Architecture

One embodiment of the electronic circuit in each transmitter unit is shown in FIG. 8. FIG. 8 is a block diagram of a transmitter module 800. Module 800 may generally correspond to transmitter 115 of FIG. 1B. Remote sensor ICs can be chosen from a wide variety of commercially-available components. One embodiment of the transmitter module 800 is discussed in the following.

Two analog data are amplified using amplifier 802 (which may be a differential amplifier), digitized using ADC analog to digital converter 804 (which may have 8 inputs, and 8-12 bit digitization of the inputs), and sent to the transceiver 808 through a microcontroller 806 (12C series microcontroller) The 12C microcontroller 806 may sequence and buffer data between the ADC 804 and an encoder circuit 810 connected to transceiver 808. In this case, transceiver 808 may operate at 433.92 MHz (having a range of about 700 feet) so as not to interfere with other communications. However, other frequencies may be used above or below 433 MHz may be used, such as 866 MHz. The transceiver frequency can be chosen to fit into an existing wireless network in the case where many of the units are networked (with unique identifiers that may be provided by the microcontroller 806.) The other components can be chosen from various manufacturers to conform to the temperature range experienced by the environment of the electronics.

One embodiment of the present invention may operate in accordance with the following discussion. Two temperatures readings may be taken using thermocouples 118 (presently Type J) (shown in FIG. 1). T and TA represent, respectively, the splice/cable temperature and the ambient (electronics housing) temperature. They are input into a differential amplifier 804 (one commonly available example of such an amplifier is the Analog Devices AD594, produced by Analog Devices of Norwood, Mass.) whose output is the difference T−TA. A/D converter 804 is preferably programmed to scan its input at regular intervals and save the corresponding digital values to its on-chip RAM. In one embodiment the A/D 804 is an 8-bit (0.1° C. accuracy) Maxim MAX1036. Data is preferably continually being taken and digitized. The on-board micro-controller (8-bit Atmel AT89C2051) 806 preferably controls the transfer of a byte (8-bit word) from the A/D 804 RAM memory to the transceiver (ABACOM ATRT100-433) 808 through the Tx control integrated circuit 810 (hereinafter, “IC”). The Tx control IC 810 uses UART communication at 2400, 8, N, 1 format, which corresponds to: 2400 baud, 8 bits at a time with no parity. Additionally, in this embodiment, the transceiver, capable of communicating up to 700 feet, is not powered until the Tx control IC 810 transfers the data to transceiver 808. The clock 812 (“clk” oscillator) synchronizes data digitization and transfer. It should be noted that the specific aforementioned parts are not required for the invention, but rather only depict one possible embodiment of the invention and could be replaced by other suitable, commonly-available parts.

Differential paths for respective analog signals may be used to cancel system noise that affects all the analog signals. A/D 804 has multiple inputs. Therefore, the unit can be expanded by adding front-end amplifiers, to collect other types of data (for example, strain or resistance data) from a particular cable/splice location. The on-board microprocessor 806 adds flexibility through programming, in conducting the data transfer from A/D 804 to transmitter 808.

In this embodiment, the transceiver section 808 consumes about 25 mA at 4.5V compared to the remainder (of the circuit of FIG. 8) consuming about 2 mA at 4.5V. A more expensive transceiver may be used to allow full duplex communications with a base station (not shown). The circuit may be implemented on a 2″×3″ printed circuit board. Nevertheless, the size of the electronics PCB can be significantly reduced, thereby, reducing the size of the sensor 200. This reduction in size may be important for reducing the perturbing effect of the sensor 200 mass on the measured data.

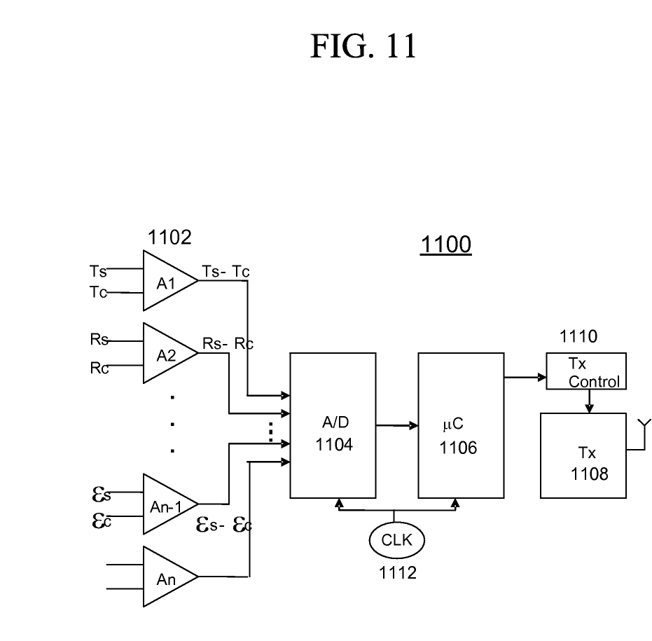

FIG. 8 illustrates one analog data path leading into ADC 804. However, as shown in FIG. 11, the analog side of ADC 804 may be easily configured to receive multiple inputs since the ADC multiplexes multiple inputs into one serial output.

### Data Communication Network

FIG. 9 is a block diagram of a data collection architecture 900 that may include a wireless network layer/data communication intermediary and a central master control according to an embodiment of the invention.

Network 900 may include base computer 902 (also central, master control computer 902), data acquisition computer 904, cable/splice location 1 906, cable/splice location 2, and one or more sensors 200 located at each cable/splice location. In one embodiment, data acquisition computer 904 may be a wireless network layer/data communication intermediary.

The individual remote sensor units 200 (FIGS. 1-3) may be part of a wireless data network 900, as shown in FIG. 9. FIG. 9 shows a wireless Data collection architecture. A transmitter 808 (FIG. 8) on each sensor 200 may wirelessly sends its measurement data (and data that identifies the sensor 200 providing the measurement data) to a centralized data collection point 904, upon being interrogated by a controlling base station computer 902.

Thus, a basic network process according one embodiment to is poll and send. The poll may be transmitted from a central master unit 902 that may be connected to the internet via a service provider or a private company network (typically analog). The remote slave units with a unique identifier may also be connected to the internet and send their data to the master 902 upon receiving the poll. Since the power transmission lines may not be in readily accessible remote locations (whether the lines are overhead or underground), the remote units may not be able to be readily and/or economically repaired and maintained. Therefore, the remote transmitter units and their housings are preferably designed for durability and resiliency in harsh ambient (outdoor four seasons) conditions, and in proximity to live transmission lines (possibly carrying current of 1000 amps or more at voltages of 200 KV or more and at temperatures of 100° C. and above).

In one embodiment of the invention, the central (master) control computer 902, which may be implemented as a base computer having an RS-232 full duplex communication capability (or other suitable protocol), sends a “SEND!” signal over a wireless link, to activate the transceivers in the circuits of each of sensors at locations 906 and 908. Each of locations 906 and 908 may include any number of needed sensors 200. The discussion of FIG. 5 described four sensors 200 being disposed at a single cable/splice location. However, fewer or more than four sensors could be deployed at each such location.

The “send” signal may be sent according to any desired schedule (hourly, daily, etc.) to prompt each transceiver 808 to send the measurement data for its sensor 200. Since central (master) computer 902 knows which sensor unit 200 receives the send signal, computer 902 may add data identifying the receiving sensor 200.

Data representing the difference between measurements (of temperature, current, line sag or other variable) for adjacent cable/splice units may then be stored. For example, data corresponding to the difference T(1a,c)−T(1a,s) may be stored at computer 902 or at computer 904. A failure warning may be sent by base computer 902 if the stored “difference” data exceeds a specified threshold that is indicative of a failure condition. It is noted that using the architecture of a controlling base computer 902 preferably eliminates the need to synchronizing clocks across all sensor units 200.

While the above embodiment was described in terms of a network employing wireless communication, wired communication could also be used, in either all or part of network 900. Data may then be stored, analyzed and plotted within the software of a central data collection point, such as central (master) computer 902, and/or connected to wireless a network layer/data communication intermediary 904.

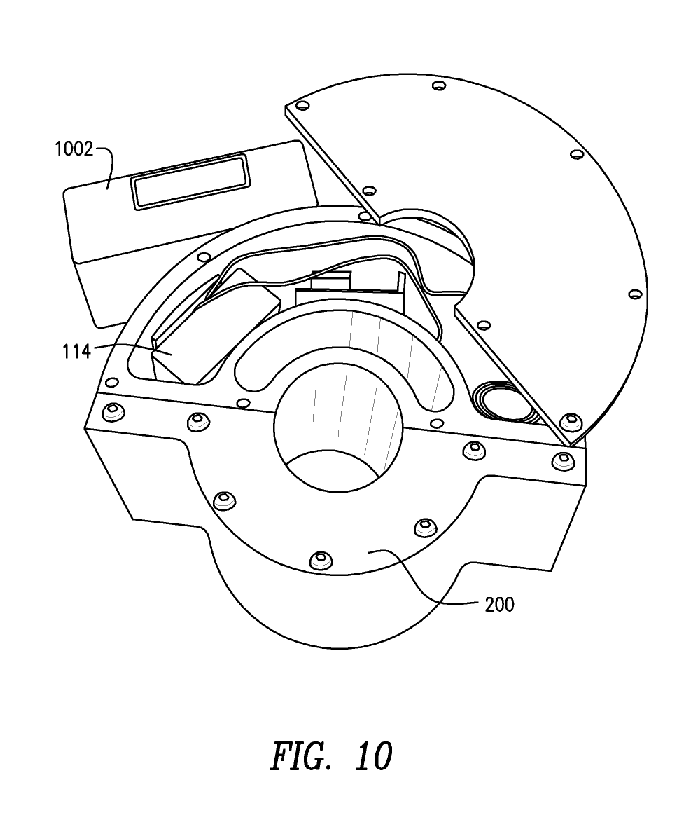

In one embodiment, a preliminary weather-tight aluminum housing which clamps onto each cable/splice may be built to house each sensor 200. A receiver 1002 may also be built to display data on an LCD. FIG. 10 shows the sensor PCB 114 mounted in the housing of sensor 200. In the embodiment of FIG. 10, the cover plate shown rotated out of the closed position in the clockwise direction may have a diameter of about ten inches. However, diameters of the cover plate and of the corresponding portion of sensor 200 that are less than or greater than ten inches may be employed.

In another embodiment, sensor 200 may include a rugged low-cost multi-channel temperature/strain/resistance sensor module with built-in calibration capability. One application for the sensor 200 is to monitor the condition of the splice between runs of power cables. Both retrofitting into the existing network and incorporating into additions to the network are possible using embodiments of the invention. Providing low cost sensor modules 200 is since the “smart” splice may become a permanently installed “capital” improvement within a power transmission network.

Since power cables are either above ground or underground, accessibility and low-voltage power are key issues. As described above with respect to the embodiments of the invention, the accessibility issue may be addressed by (1) wireless data transmission to a convenient base station connected to a wired or wireless data communication network and/or (2) careful design of the electronics/power source for prolonged (very long interval between servicing or replacement) service life. The power issue may be further complicated by the inaccessibility of the power supply providing power to the electronic circuits that process and transmit the data.

Moreover, one possible indication of splice failure is the temperature difference between the splice and the adjacent cable. For a healthy splice, the electrical resistance of the contact between the splice and the cable is small compared to the cable resistance. Since the splice has a larger diameter than the cable, the splice has a larger area (for heat loss) and therefore usually operates at a lower temperature than the adjacent cable. Another possible indication of splice failure is the resistance difference between the splice and the adjacent cable. The splice resistance becoming greater than that of the adjacent cable may also indicate imminent failure of the splice and/or the cable.

Another factor indicative of a possible failure condition is increased strain at the splice/cable connection. Increased strain may correlate with cable sag—another important issue for power transmission. Further development of the low-added-cost “smart” splice may include strain and resistance measurements which can then be wirelessly transmitted to a base station.

FIG. 11 is a block diagram of a circuit 1100 having multiple data inputs and a transmitter module 1208 according to an embodiment of the invention.

One or more differential analog signals (for example, a signal proportional to the temperature difference Tsplice−Tcable) may be amplified by amplifier bank 1102 and digitized by A/D converter (ADC) 1104 (which may be an 8-input ADC with an output having between 8 to 12 bits), which may produce a digital output signal. In an embodiment, an 8-bit ADC may generate an output signal having an accuracy of 1° C. and 0.1° C. resolution. Micro-controller (μC) 1106 (which may be a model AT89CC2051) preferably sequences the digitized data and sends the digitized data to the transmitter 1108 using transmitter control 1110. The programming of microcontroller 1106 may determine the transfer rate for data transmitted out of microcontroller 1106. The transmission frequency and power employed by transmitter 1108 are chosen to communicate to a local wireless base station. Communication with data acquisition computer 904 or base computer 902 may employ a carrier frequency of about 900 Megahertz (MHz). After being received, the transmitted data may be stored on a computer connected to a wired or wireless communication network.

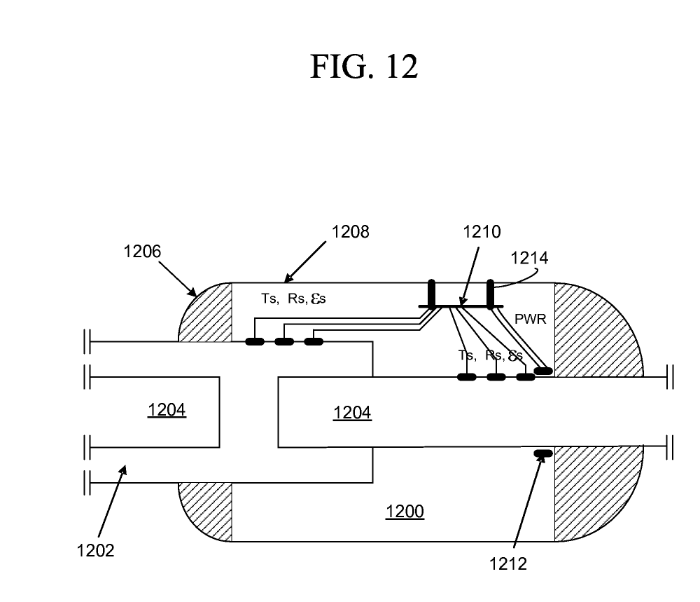

FIG. 12 shows one embodiment of an enclosure 1200 for the electronic circuits of sensor 200. Enclosure 1200 can straddle the splice and cable, to measure the desired data (for example, T, θ, R . . . ) for both the splice and the cable (conductor). In this embodiment, enclosure 1200 may include a splice cylinder 1202, a cable cylinder 1204, a corona guard 1206, a sensor cylinder 1208, an electronics PCB 1210 coupled to an insulating standoff 1214, and a toroid 1212 for power harvest.

Alternatively, enclosure 1200 could be made smaller and be placed on only the cable 1204 or the splice 1202 as a single unit. The benefit of this single unit is small size and possibly ease of installation. Because of the negligible cost of the electronics and lower cost of the enclosure, the total cost of the single unit may also be less than that of the larger enclosure straddling the cable and splice.

The toroid 1212 may be selected so as to operate in the saturation region (accounting for any magnetic flux leakage at 50-60 Hz) so that a reasonable number of turns (series resistance) provides the corresponding AC induction over the full conductor current range of 50 A to 3000 A.

The design of enclosure 1200, and the installation thereof may be configured to give good mechanical contact to a hot splice/cable (T of about 200° C., °550 kV). The thermal and mechanical properties of enclosure 1200 are preferably such that the enclosure 1200 properties do not distort the data to be measured (for example, increase local temperature or relieve local strain). Further, the thermal design should provide sufficient cooling for the electronic circuitry to operate at about 150° C. when the enclosure 1200 is close to the much hotter cable or splice.

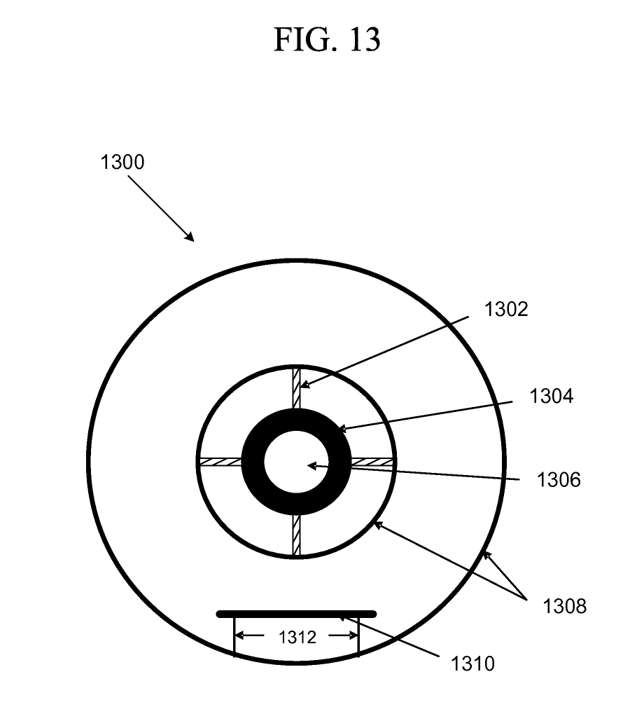

FIG. 13 is a sectional end view of a power line enclosed within a clamped enclosure forming part of a remote unit in which thermal insulator spokes may be used to reduce heat flow to the remote sensor unit electronics. The assembly 1300 of FIG. 13 may include power line 1306, clamp 1304, electronic circuitry 1310, enclosure 1308 for circuitry 1310, and/or spokes 1302 disposed between power line 1306 and an interior surface of enclosure 1308. Standoffs 1312 may be employed to separate electronic circuitry 1310 from the surfaces of enclosure 1308.

Spokes 1302 may be selected and/or designed so as to have low thermal conductivity to diminish the transmission of heat to, and the operating temperature of, enclosure 1308 and electronic circuits 1310 therein. Clamp 1304 may be made of steel and may include a hard rubber gasket and a power harvesting apparatus. Power line 1306 is preferably a standard conductor, or utility cable, in an overhead (or underground) transmission line system. Enclosure 1308 may be split into two (or more) parts and secured in an assembled condition using a hinge, along with a suitable clamp.

Additionally, in the case of overhead transmission lines, enclosure 1308 may be installed beneath the power line 1306, toward the ground, and away from direct sunlight. Further, the electronics enclosure 1308 may be provided with a polished finish to reduce radiative heat transfer thereto. The profile of enclosure 1308 is also important. The electronic circuitry 1310 should preferably be mounted in a non-obtrusive enclosure 1308 that has an aerodynamic profile. In addition, enclosure 1308 may include rounded edges to prevent the occurrence of corona discharges.

Assuming that the cost of the electronic circuitry is negligible compared to the costs of installation and maintenance and that the electronic circuitry is properly enclosed, and ages slowly because of environmental factors, a large maintenance cost is associated with any limited lifetime power source for the circuitry.

Therefore, one power source lifetime extending strategy, according to the invention, is to tap into the relatively unlimited power available from the power cable and/or to use a renewable power source for the times where the power “harvesting” design is not sufficient to power the electronics.

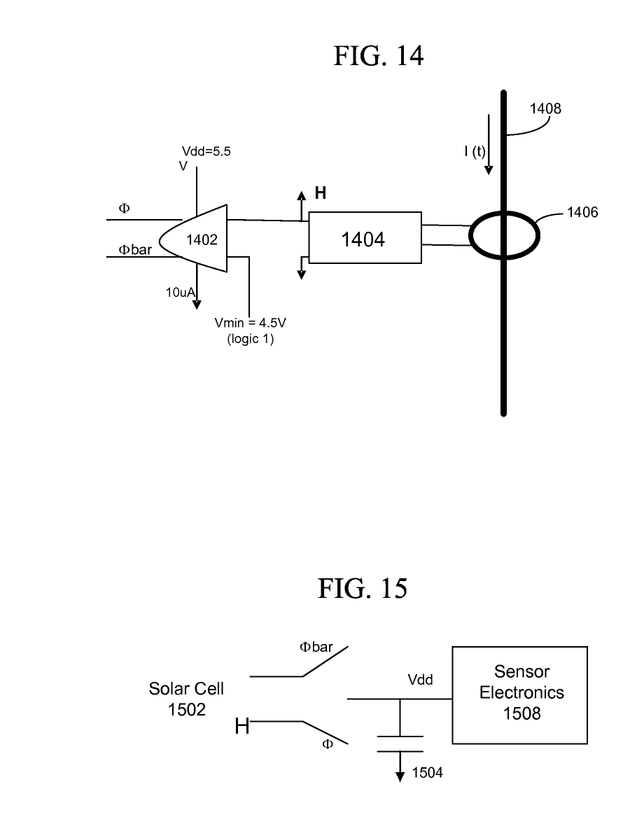

FIG. 14 is a schematic view of a power harvesting system according to an embodiment of the invention. FIG. 14 presents a variation of the circuit presented in FIG. 3 hereof.

Locally “harvesting” the power for the electronic circuitry of sensor 200 (not shown in FIG. 14) from power cable 1408 may provide local power to the electronics without the need for low voltage wires or batteries. As shown in FIG. 15, this may be achieved by including in the sensor module enclosure a circuit 1400 to inductively couple to the AC current flowing in the cable 1408 of the power transmission network. As shown in FIG. 14, the inductive coupling (which includes toroidal winding 1406) obtains an AC voltage which should preferably be in-situ rectified to DC.

Circuit 1400 may include AND logic circuitry 1402, full bridge rectifier 1404, toroidal winding 1506, and power cable 1408. Since the current flowing through cable 1408 varies with the power transmission load being delivered, the inductive coupling (n wire turns wound around toroid 1406 that may be clamped around cable 1408) may be designed to produce a peak voltage of 5 Volts DC for a median transmission load. In an embodiment, the power harvest may be deactivated for loads outside of a predetermined window, that is for loads outside of about 4.5-5.5 volts. Where the current flowing through power cable 1408 is not suitable for powering the electronic circuitry of sensor 200, one or more other sources of DC power may be substituted for the power harvest source, in order to power the electronic circuitry (not shown in FIG. 14).

In one embodiment, the actual inductively coupled voltage may be compared to the nominal 5V required by the electronics. If the inductively generated voltage value is within a reasonable range of the 5 volts needed, the inductively generated power may be directed so as to charge a capacitor supplying power to the electronics (not shown in FIG. 14). Otherwise, high-quality solar photovoltaic cells can be employed to charge the capacitor supplying power to the electronics. Thus, in this case, the solar cells are the renewable back-up power source.

FIG. 15 is a schematic view of a power harvesting system 1500 according to another embodiment of the invention. System 1500 may include solar cell 1502 which may provide an output at 4.5 volts, capacitor 1504, and/or sensor electronics (electronic circuitry) 1508.

One or more solar cells 1502 may be used as a backup power source in the case where the current in power cable 1408 is insufficient to power sensor electronics 1508. One alternative to providing a backup power source is for the sensor electronics 1508 to send a signal indicating the data flow is being stopped because insufficient power is being supplied to electronics 1508. This may be done with additional logic to determine when the electronics 1508 operates at minimum Vdd, with the warning being sent by the micro-controller 1106 (FIG. 11).

For most embodiments of the invention, the power consumed by the electronics 1508 of sensor unit 200 should preferably be minimized. This power consumption is typically dominated by the transmitter 1108 (FIG. 11) which may use about 30 mA at 5 volts. Power consumption can be minimized by turning the transmitter 1108 (and other ICs) ON only when data needs to be transmitted.

Further power savings may be achieved by comparing current measurement data at sensor electronics 1508 with previously obtained data, transmitting data only when the data significantly changes. In some embodiments of the invention, periodic data (along with a location identifier header packet) transmission may be beneficial for indicating that a sensor 200 in an operational condition.

In an embodiment, an alarm may be used to indicate the reversal of an expected cable and splice temperature disparity, and thereby prompt a service technician to take action. Suitable power-saving and power-transmission functionality may be coded into the micro-processor 1106 (FIG. 11) of the electronics 1508.

Both switching of power to, and minimizing power consumed by, the electronics 1508 are relevant factors in determining the lifetime of the power source for the electronics 1508. The upper bound on solar cell lifetime may be controlled by the degradation of the light transmission properties of the encapsulating window (usually a form of Teflon®) used for the solar cells. This degradation is substantially purely environmental. Another upper bound on solar cell lifetime is the solar cell material life which is longer for silicon than Teflon. This material life can be further improved by design, e.g., by switching in the inductively generated and rectified voltage.

The next bound on solar cell lifetime may be set by the charge/discharge cycling of the capacitor 1504. The capacitor 1508 cycling may be set by material properties but can be substantially improved by decreasing the number of discharge cycles (for example, by using low-power electronics with a sleep mode, and by transmitting new data only when a significant change has occurred in the data).

In the design of the electronics module, the analog sensor data may be in differential form. In an embodiment, all analog circuits may be fully differential with high common mode rejection ratio. This provides some immunity to the 60 Hz power transmission noise. In one embodiment of the invention, the analog data may be digitized before transmission to the desired receiver. Digital data transmission preferably provides additional noise immunity. Additional passive, high-pass filtering before digitization may further reduce noise coupling. Finally, electronic components may be enclosed within a shielded metal box of minimum size.

In some embodiments of the invention, the operating ambient for the electronics is assumed to be air with at least a multiple scattering path between transmitter and receiver.

Thus, an overhead high voltage transmission line remote sensor has been provided. Persons skilled in the art will appreciate that the present invention can be practiced by other than the described embodiments, which are presented for purposes of illustration rather than of limitation, and the present invention is limited only by the claims which follow.

1. A high voltage transmission line sensor system comprising:
an electronics chamber that transmits high voltage line data to a base station;
a clamping mechanism adapted to clamp the sensor system to a high voltage transmission line; and
a coupling device that couples the electronics chamber to the clamping mechanism, wherein the coupling device has low thermal conductivity to minimize heat transfer between the clamping mechanism and the electronics chamber.

2. The sensor system of claim 1 wherein the coupling device comprises at least one screw.

3. The sensor system of claim 1 wherein the coupling device comprises a plurality of spokes.

4. The sensor system of claim 1 further comprising a magnetic induction power harvesting circuit that harvests power from the overhead high voltage transmission line.

5. The sensor system of claim 1, wherein the clamping mechanism further comprises a spring/roller clamp.

6. The sensor system of claim 1, further comprising a central hardware system that provides lateral infrared temperature measurement.

7. The sensor system of claim 1, further comprising a laser absorption system for angle measurement of the high voltage transmission line.

8. The sensor system of claim 1, further comprising an expandable wireless network architecture for data acquisition from remote units.

9. The sensor system of claim 1, further adapted for use with an overhead high voltage transmission line.

10. The sensor system of claim 1, further adapted for used with an underground high voltage transmission line.

11. A sensor system within a high voltage power transmission system comprising:
at least one sensor for measuring at least one characteristic of a conductor of the power transmission system;
an electronic circuit for generating data corresponding to the sensor measurement; and
a power harvesting system for providing power from the conductor to operate the electronic circuit.

12. The sensor system of claim 11 wherein the power harvesting system derives power from the conductor by induction.

13. The sensor system of claim 11 wherein the power harvesting system comprises:
a toroid arranged around at least a portion of a circumference of the conductor.

14. The sensor system of claim 13 wherein the toroid is disposed around about one half of the circumference of the conductor.

15. The sensor system of claim 13 wherein the toroid substantially completely surrounds the conductor.

16. The sensor system of claim 11 further comprising:
a transmitter for transmitting the measurement data from the sensor system to a data acquisition computer.

17. The sensor system of claim 11 wherein the at least one characteristic includes a characteristic selected from the group consisting of: temperature of the conductor; current through the conductor; and line sag of the conductor.

18. A sensor system within a high voltage power transmission system comprising:
at least one infrared detector for measuring a temperature of a conductor of the transmission system based on a surface emission therefrom;
a central component, within the sensor system, for receiving measurements from the at least one infrared sensor;
an electronic circuit for generating data corresponding to the infrared detector measurements; and
a transmitter for transmitting the measurement data to a data acquisition computer.

19. The sensor system of claim 18 comprising;
a second infrared detector for measuring a temperature of a splice coupled to the conductor.

20. A data communication network for an electric power grid, the network comprising:
a central communications hub;
a plurality of data acquisition computers located at a plurality of respective locations in communication with the power grid; and
a power line test apparatus located at each of a plurality of testing locations, wherein the test apparatuses are configured to measure at least one operating characteristic of a transmission line at each said testing location, and wherein each said test apparatus is configured to be in communication with a selected one of the data acquisition computers.
